(19) United States
(12) Patent Application Publication
(10) Pub. No.: US 2019/0031123 A1
(43) Pub. Date: Jan. 31, 2019

(54) OPERATING DEVICE AND OPERATING DEVICE MANUFACTURING METHOD

(71) Applicant: KABUSHIKI KAISHA TOKAI-RIKA-DENKI-SEISAKUSHO, Aichi (JP)

(72) Inventors: Shigeki YOSHIDA, Aichi (JP); Suguru FUJISAKI, Aichi (JP)

(21) Appl. No.: 16/073,655

(22) PCT Filed: Jan. 24, 2017
(86) PCT No.: PCT/JP2017/002370

§ 371 Date: Jul. 27, 2018

(30) Foreign Application Priority Data
Feb. 4, 2016 (JP) 2016-020044

(51) Int. Cl. B60R 16/02; H05K 5/02

(52) U.S. Cl. CPC B60R 16/0215; B60R 1/06; H05K 5/0217

(57) ABSTRACT

In a vehicle door mirror device, a terminal is provided inside reinforcement, and the terminal is electrically connected to a motor. Moreover, when molding the reinforcement, the terminal is exposed by a first exposing hole of the reinforcement. A first protrusion portion is formed at a perimeter of the first exposing hole of the reinforcement when molding the reinforcement. After the reinforcement has been molded, the first protrusion portion is then moved into the first exposing hole while in a melted state and the first protrusion portion is caused to oppose the terminal. The first protrusion portion thereby closes off the first exposing hole, enabling infiltration of water to the terminal to be inhibited.

### TECHNICAL FIELD

The present invention relates to an operating device with wiring inside a layout member electrically connected to an operating mechanism, and to a method of manufacturing such an operating device.

### BACKGROUND ART

In an automobile electrically controlled mirror described in Japanese National-Phase Publication No. 2002-529297, a conductor is provided in a reinforcement element, and the conductor is electrically connected to an electro-mechanical means.

This automobile electrically controlled mirror is an example of a case in which a conductor is disposed inside a reinforcement element by molding (insert molding) the reinforcement element while in a state supported by a support member. In this case an exposing hole is formed in the reinforcement element by the support member, and the conductor is exposed through the exposing hole, with the possibility of liquid (for example, water) infiltrating to the conductor through the exposing hole.

### SUMMARY OF INVENTION

### Technical Problem

In consideration of the above circumstances, an object of the present invention is to obtain an operating device capable of inhibiting infiltration of liquid to wiring, and a method of manufacturing the operating device.

### Solution to Problem

An operating device of a first aspect of the present invention includes an operating mechanism, a layout member, and a solidified portion. The operating mechanism is electrically operated. The layout member includes wiring electrically connected to the operating mechanism and disposed within the layout member. The solidified portion is provided at the layout member, is solidified separately from a perimeter thereof, opposes the wiring, and inhibits infiltration of liquid to the wiring.

An operating device of a second aspect of the present invention is the operating device of the first aspect of the present invention, wherein the solidified portion is provided on one side face and another side face of the layout member, and the wiring is disposed between the solidified portion and the solidified portion.

An operating device of a third aspect of the present invention is the operating device of the first aspect or the second aspect of the present invention, wherein the wiring is parted at a solidified portion opposing portion.

An operating device of a fourth aspect of the present invention is the operating device of any one of the first aspect to the third aspect of the present invention, wherein the solidified portion is projected from the layout member.

An operating device of a fifth aspect of the present invention is the operating device of the fourth aspect of the present invention, wherein a recess portion is provided in a projecting leading end portion of the solidified portion.

A method of manufacturing an operating device of a sixth aspect of the present invention is a method to method of manufacturing an operating device that includes an electrically operated operating mechanism and a layout member including wiring electrically connected to the operating mechanism and disposed within the layout member. The method includes providing an exposing hole in the layout member to expose the wiring, and moving a portion of a perimeter of the exposing hole in the layout member into the exposing hole while in a melted state to cause the portion to oppose the wiring, and solidifying the portion to form a solidified portion that inhibits infiltration of liquid to the wiring.

An operating device manufacturing method of a seventh aspect of the present invention is the operating device manufacturing method of the sixth aspect of the present invention, wherein a protrusion portion is provided at the exposing hole perimeter of the layout member, and the solidified portion is configured by the protrusion portion by moving the protrusion portion into the exposing hole while in a melted state so as to cause the protrusion portion to oppose the wiring, so as to inhibit infiltration of liquid to the wiring.

An operating device manufacturing method of an eighth aspect of the present invention is the operating device manufacturing method of the seventh aspect of the present invention wherein the protrusion portion is provided at an entire periphery of the exposing hole of the layout member.

An operating device manufacturing method of a ninth aspect of the present invention is the operating device manufacturing method of any one of the sixth aspect to the eighth aspect of the present invention wherein the solidified portion is projected from the layout member.

### Advantageous Effects

In the operating device of the first aspect of the present invention, the wiring is disposed within the layout member, the wiring is electrically connected to the operating mechanism, and the operating mechanism is electrically operated.

The solidified portion is provided at the layout member, the solidified portion is solidified separately from the perimeter thereof, and the solidified portion opposes the wiring, and inhibits infiltration of liquid to the wiring. This thereby enables infiltration of liquid to the wiring to be inhibited.

In the operating device of the second aspect of the present invention, the solidified portion is provided on the one side face and the other side face of the layout member, and the wiring is disposed between the solidified portion and the solidified portion. This thereby enables infiltration of liquid to the wiring to he inhibited from the one side face and the other side face of the layout member.

In the operating device of the third aspect of the present invention, the wiring is parted at a solidified portion opposing portion. This means that, after the wiring has been parted through an exposing hole in a state in which the exposing hole is provided in the layout member and the wiring is exposed, the solidified portion can be provided opposing a parted portion of the wiring.

In the operating device of the fourth aspect of the present invention, the solidified portion is projected from the layout member. Thereby enables infiltration of liquid to the. wiring to be effectively inhibited.

In the operating device of the fifth aspect of the present invention, the recess portion is provided in the projecting leading end portion of the solidified portion.

An exposing hole is provided at a portion of the layout member where the solidified portion is to be provided, and in a state in which the wiring is exposed from the exposing hole, the recess portion is provided in the projecting leading end portion of the solidified portion by moving portions of the layout member at the entire periphery of the exposing hole into the exposing hole. This enables excellent inhibition of infiltration of liquid to the wiring.

In the operating device manufacturing method of the sixth aspect of the present invention, in the operating device the wiring is disposed within the layout member, the wiring is electrically connected to the operating mechanism, and the operating mechanism is electrically operated.

The exposing hole is provided in the layout member to expose the wiring. Moreover, the portion at the exposing hole perimeter of the layout member is moved into the exposing hole while in a melted state so as to oppose the wiring, and the portion is solidified so as to configure the solidified portion and to inhibit infiltration of liquid to the wiring. This thereby enables infiltration of liquid to the wiring to be inhibited.

In the operating device manufacturing method of the seventh aspect of the present invention, the protrusion portion is provided at the exposing hole perimeter of the layout member. Moreover, the protrusion portion configures the solidified portion by moving the protrusion portion into the exposing hole while in a melted state so as to cause the protrusion portion to oppose the wiring, inhibiting infiltration of liquid to the wiring. This enables the solidified portion to be easily provided.

In the operating device manufacturing method of the eighth aspect of the present invention, the protrusion portion is provided at the entire periphery of the exposing hole of the layout member. This enables the protrusion portion to be moved from the entire periphery into the exposing hole in a melted state, enabling excellent inhibition of infiltration of liquid to the wiring.

In the operating device manufacturing method of the ninth aspect of the present invention, the solidified portion is projected from the layout member. This enables infiltration of liquid to the wiring to be effectively inhibited.

### BRIEF DESCRIPTION OF DRAWINGS

FIG. 1 is an exploded perspective view of a vehicle door mirror device according to an exemplary embodiment of the present invention, as viewed from a vehicle front side and vehicle width direction inside.

FIG. 2 is a cross-section of relevant portions of the vehicle door mirror device according to the exemplary embodiment of the present invention, as viewed from a vehicle width direction outside.

FIG. 3 is a perspective view of a visor body of the vehicle door mirror device according to the exemplary embodiment of the present invention, as viewed from a vehicle rear side and vehicle width direction inside.

FIG. 4A is an overall perspective view of reinforcement of a vehicle door mirror device according to an exemplary embodiment of the present invention, as viewed from a vehicle front side and vehicle width direction outside.

FIG. 4B is a perspective view of relevant portions of a reinforcement of the vehicle door mirror device according to the exemplary embodiment of the present invention, as viewed from a vehicle front side and vehicle width direction outside.

FIG. 5A is an overall perspective view of the reinforcement of the vehicle door mirror device according to the exemplary embodiment of the present invention partway through manufacture, as viewed from a vehicle front side and vehicle width direction outside.

FIG. 5B is a perspective view of relevant portions of the reinforcement of the vehicle door mirror device according to the exemplary embodiment of the present invention partway through manufacture, as viewed from a vehicle front side and vehicle width direction outside.

### DESCRIPTION OF EMBODIMENTS

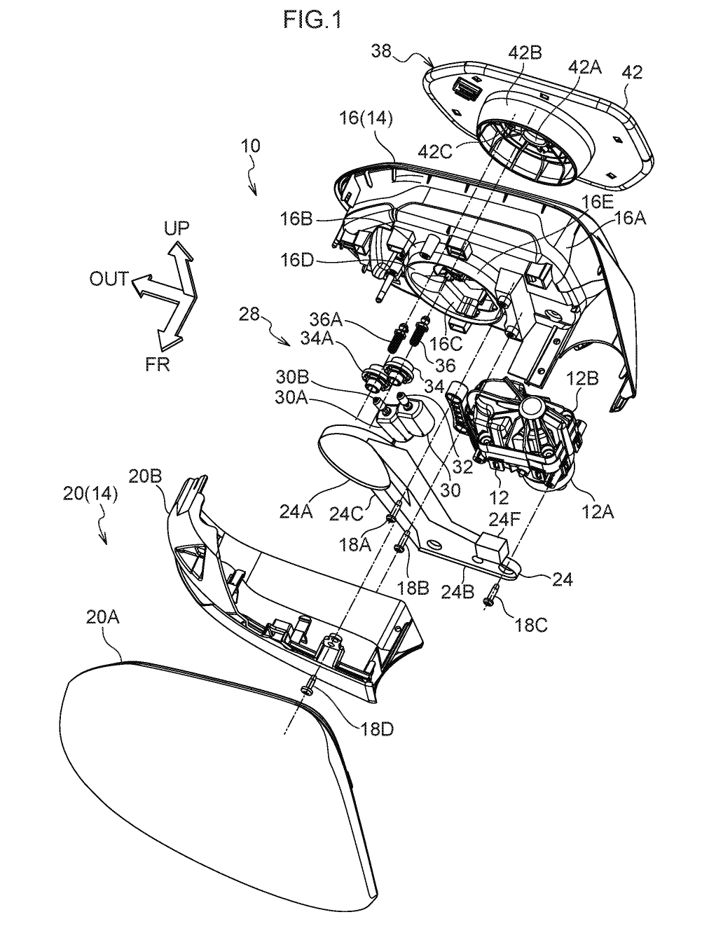

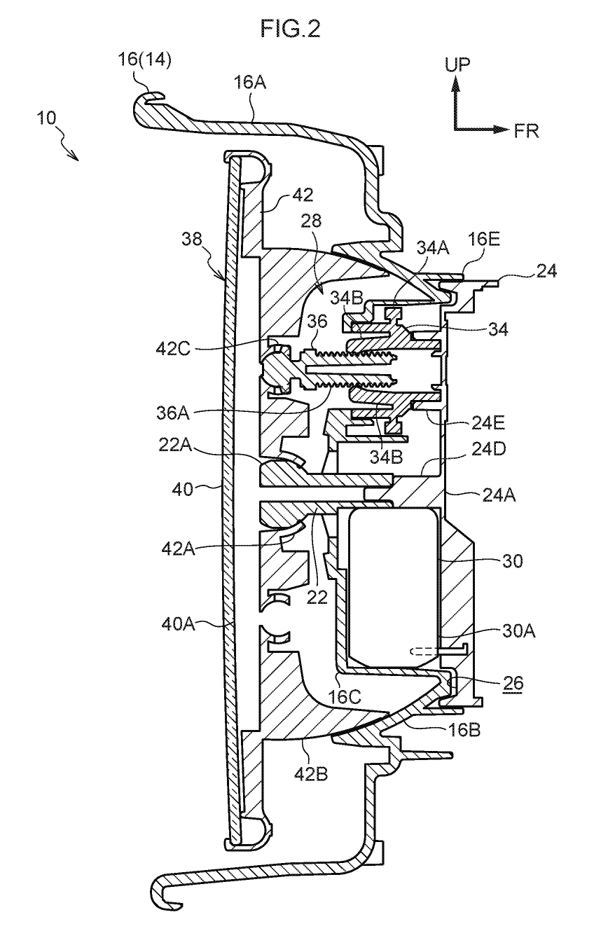

FIG. 1 is an exploded perspective view of a vehicle door mirror device 10 (vehicle visual recognition device), serving as an operating device, according to an exemplary embodiment of the present invention, as viewed from a vehicle front side and vehicle width direction inside (vehicle left side). FIG. 2 is a cross-section of relevant portions of the vehicle door mirror device 10, as viewed from a vehicle width direction outside (vehicle right side). Note that in the drawings the arrow FR indicates a direction toward the vehicle front, the arrow OUT indicates a vehicle width direction outside, and the arrow UP indicates upwards.

The vehicle door mirror device 10 according to the present exemplary embodiment is supported at an outside of a door (front side door, vehicle body side) of a vehicle.

As illustrated in FIG. 1, the vehicle door mirror device 10 includes a stowing mechanism 12. A stand 12A, which serves as a base member, is provided in the stowing mechanism 12. The vehicle door mirror device 10 is supported on the door by the stand 12A being supported at a vehicle front side end of an up-down direction intermediate portion of the door. A swing body 12B is supported by the stand 12A. The swing body 12B is swung about a vertical axis with respect to the stand 12A by electrically operating the stowing mechanism 12. The swing body 12B is electrically connected, through the inside of the stand 12A, to a controller (not illustrated the drawings) on the vehicle body side, and the stowing mechanism 12 is electrically operated under control by the controller.

A visor 14, which is made from resin and serves as an outer peripheral body, is supported on the swing body 12B of the stowing mechanism 12. A visor body 16, which serves as a housing body, is provided to the visor 14. The swing body 12B is fixed to a vehicle front side of a vehicle width direction inside end portion of the visor body 16, such as by fastening a first screw 18A and a second screw 18B, which serve as assembly members. A visor cover 20, which has a curved plate shape and serves as a covering member, is assembled at the vehicle front side of the visor body 16 with reinforcement 24, described below, interposed therebetween. An outer periphery of the visor cover 20 is fitted to an outer periphery of the visor body 16, so that the visor cover 20 covers the vehicle front side of the visor body 16. An upper cover 20A is provided at an upper side of the visor cover 20, and a lower cover 20B is provided at a lower side thereof. The visor cover 20 is configured by combining the upper cover 20A and the lower cover 20B.

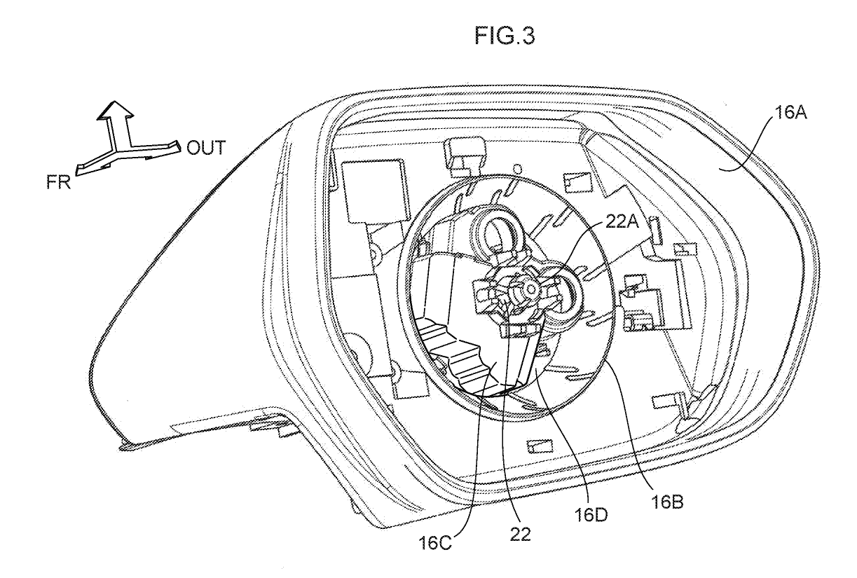

As illustrated in FIG. 1 to FIG. 3, a substantially cuboid box-shaped housing wall 16A, which serves as a housing section, is provided to the visor body 16. The inside of the housing wall 16A is open toward the vehicle rear side.

A support wall 16B (case lower portion), which serves as a support portion, is integrally provided to a vehicle front side wall (bottom wall) of the housing wall 16A. The support wall 16B projects out to the vehicle front side and vehicle rear side of the vehicle front side wall of the housing wall 16A. The support wall 16B is substantially cylindrical in shape, and is disposed such that a center axis line of the support wall 16B is parallel to the vehicle front-rear direction. The support wall 16B has a spherical wall shape, with the internal diameter dimension of the support wall 16B gradually increasing on progression toward the vehicle rear.

A covering wall 16C (case upper portion), which has a receptacle shape and serves as a covering portion, is provided inside the support wall 16B. The entire periphery at the vehicle front side end of the covering wall 16C is integrated to the entire periphery at the vehicle front side end of the support wall 16B. A coupling wall 16D having a flat plate shape is integrally provided between the vehicle front side end of the covering wall 16C and the vehicle front side end of the support wall 16B. The coupling wall 16D couples together the vehicle front side end of the covering wall 16C and the vehicle front side end of the support wall 16B at parts where the vehicle front side end of the covering wall 16C and the vehicle front side end of the support wall 16B are not directly integrated together. The inside of the covering wall 16C is open toward the vehicle front side of the support wall 16B. The inside of the covering wall 16C is thereby open toward the vehicle front side of the housing wall 16A.

A fitting cylinder 16E, which has a circular cylindrical shape and serves as a perimeter portion, is integrally provided to a vehicle front-rear direction intermediate portion at the outer peripheral face of the support wall 16B. The fitting cylinder 16E projects out from the support wall 16B toward the vehicle front side, and is disposed coaxially to the support wall 16B.

A retention tube 22, which has a substantially circular tube shape and serves as a central support portion (retention portion), is integrally provided to a vehicle rear side wall (bottom wall) of the covering wall 16C. The retention tube 22 projects out to the vehicle front side and the vehicle rear side of the vehicle rear side wall of the covering wall 16C, and is disposed coaxially to the support wall 16B. A retention ball 22A having a substantially spherical shape is provided at a vehicle rear side end portion of the retention tube 22. A peripheral face of a vehicle front side portion of the retention ball 22A has a spherical face profile, with the center of the spherical face profile aligned with a center of the inner peripheral face of the support wall 16B.

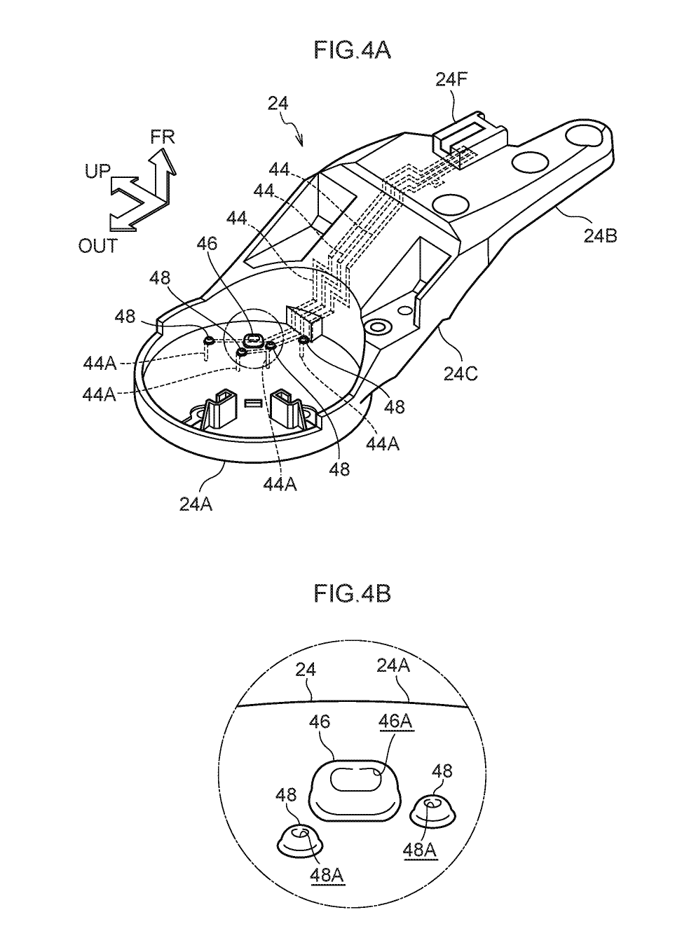

The reinforcement 24 (see FIG. 4A), which is substantially made from resin in an elongated plate shape and serves as a layout member (reinforcement body), is provided at the vehicle front side of the visor body 16 and the swing body 12B of the stowing mechanism 12. The reinforcement 24 extends in the vehicle width direction. A bottom wall portion 24A, which has a circular disk shape and serves as a blocking portion, is provided to a vehicle width direction outside portion of the reinforcement 24. An inner wall portion 24B, which has a substantially triangular plate shape, is provided to a vehicle width direction inside portion of the reinforcement 24. An inclined portion 24C, which serves as a coupling portion, is provided to a vehicle width direction intermediate portion of the reinforcement 24. The inclined portion 24C couples the bottom wall portion 24A and the inner wall portion 24B together, such that the bottom wall portion 24A is disposed at the vehicle rear side of the inner wall portion 24B.

The reinforcement 24 is fixed to the swing body 12B of the stowing mechanism 12 and to the visor body 16 by fastening the first screw 18A, the second screw 18B, and a third screw 18C or the like. The reinforcement 24 has a higher rigidity than that of the visor body 16, and the reinforcement 24 reinforces the visor body 16 and the swing body 12B. Moreover, the visor cover 20 (the lower cover 20B) of the visor 14 is fixed to the reinforcement 24 by fastening a fourth screw 18D, which serves as a fixing member. The visor cover 20 is thereby assembled to the visor body 16 with the reinforcement 24 interposed therebetween, as described above.

An insertion recess portion 26, which has a rectangular profile in cross-section, is formed around the entire periphery of an outer peripheral portion at the vehicle rear side face of the bottom wall portion 24A. The vehicle front side end of the support wall 16B of the visor body 16 is inserted into the insertion recess portion 26. The outer peripheral face of the bottom wall portion 24A is fitted inside the fitting cylinder 16E of the visor body 16. The outer peripheral face of the support wall 16B fits together with the outer peripheral face of the insertion recess portion 26. The bottom wall portion 24A thereby covers and blocks off the vehicle front side of the support wall 16B, the covering wall 16C, and the coupling wall 16D of the visor body 16, and reinforces the support wall 16B, the covering wall 16C, and the coupling wall 16D.

A fit-insertion column 24D, which has a substantially circular column shape and serves as a fit-insertion portion, is integrally provided at a central portion of the bottom wall portion 24A. The fit-insertion column 24D projects out from the bottom wall portion 24A toward the vehicle rear side, and is disposed coaxially to the bottom wall portion 24A. A leading end portion of the fit-insertion column 24D has a reduced diameter. The leading end portion of the fit-insertion column 24D is fit-inserted inside the retention tube 22 of the visor body 16 from the vehicle front side, reinforcing the retention tube 22.

Circular tube shaped support tubes 24E are integrally provided to an upper portion and vehicle width direction outside portion of the bottom wall portion 24A. Each of the support tubes 24E projects out from the bottom wall portion 24A toward the vehicle rear side, and is disposed with a center axis line parallel to the center axis line of the bottom wall portion 24A.

Three terminals 44, which have elongated plate shapes and configure wiring (see FIG. 4A), are provided embedded in the reinforcement 24. The reinforcement 24 is manufactured by molding (insert molding) in a state in which the terminals 44 are disposed inside the reinforcement 24. The terminals 44 extend along the vehicle width direction, such that the terminals are disposed extending from the inner wall portion 24B to the bottom wall portion 24A via the inclined portion 24C.

A power supply connector 24F, which has a bottomed tube shape and serves as a receptor portion, is integrally provided to the inner wall portion 24B. Base end portions (vehicle width direction inside end portions) of the terminals 44 extend inside the power supply connector 24F. The base end portions of the terminals 44 are electrically connected to the controller via the inside of the swing body 12B and the inside of the stand 12A of the stowing mechanism 12.

A leading end side portion (vehicle width direction outside portion) of one of the terminals 44 branches in two. The leading end portions of the terminals 44 (including each of the branch portions of the one terminal 44) extend from the bottom wall portion 24A toward the vehicle rear side, and configure output terminals 44A, which serve as connecting portions. There are accordingly four of the output terminals 44A provided, with the output terminals 44A being provided as two pairs.

A single first protrusion portion 46 (see FIG. 4B), which has a substantially rectangular column shape and serves as a solidified portion, is provided on each of the vehicle front side face and the vehicle rear side face of the bottom wall portion 24A. Peripheral faces of the first protrusion portions 46 are curved in convex profiles. Portions at the leading end sides of two of the terminals 44 and parted portions (severed/separated portions) of these two terminals 44 are disposed between the pair of first protrusion portions 46. The first protrusion portions 46 oppose these two terminals 44 and the parted portions of these two terminals 44. First recess portions 46A, which have substantially rectangular column shapes and serve as recess portions, are formed in leading end portions (center portions) of the first protrusion portions 46. Openings of the first recess portions 46A have substantially rectangular shapes.

Four second protrusion portions 48 (see FIG. 4B), which each have a substantially semi-spherical shape and serve as a solidified portion, are provided on the vehicle front side face and the vehicle rear side face of the bottom wall portion 24A. The peripheral faces of the second protrusion portions 48 are curved in convex profiles. Portions of the terminals 44 in the vicinity of the output terminals 44A are disposed between each of the pairs of second protrusion portions 48. The second protrusion portions 48 oppose the terminals 44. Second recess portions 48A, which have substantially semi-spherical shapes and serve as recess portions, are formed at leading end portions (center portions) of the second protrusion portions 48. Openings of the second recess portions 48A have substantially circular shapes.

A mirror face adjustment mechanism 28, which serves as an operating mechanism is retained between the covering wall 16C of the visor body 16 and the bottom wall portion 24A of the reinforcement 24.

A pair of motors 30, which serve as drive means, are provided in the mirror face adjustment mechanism 28. A main body 30A of each of the motors 30 is retained in a state clamped between the covering wall 16C and the bottom wall portion 24A. An output shaft 30B extends from the main body 30A, and a worm 32, which serves as an output member, is fixed to the output shaft 30B. A pair of the output terminals 44A of the reinforcement 24 is electrically connected to each of the main bodies 30A. Electrical power is supplied to the motors 30 and the motors 30 are driven under control by the controller to electrically operate the mirror face adjustment mechanism 28.

A pair of wheel drives 34, which are each made from resin in a substantially circular tube shape and serve as transmission members, are provided in the mirror face adjustment mechanism 28. In a state in which the vehicle front side portion of each of the wheel drives 34 is fit-inserted. into the support tubes 24E of the bottom wall portion 24A, the wheel drives 34 are clamped between the covering wall 16C and the bottom wall portion 24A and retained so as to be rotatable about their axes.

A worm wheel 34A is formed coaxially to an outer peripheral edge at an intermediate portion in the axial direction (vehicle front-rear direction) of each of the wheel drives 34. The worm wheels 34A are each meshed (engaged) with the respective worms 32 of the motors 30. Thus the worm wheels 34A are rotated by driving of each of the motors 30 so as to rotate the worms 32, and the wheel drives 34 are rotated.

A predetermined number (four in the present exemplary embodiment) of meshing claws 34B, which serve as engaging portions, are formed to an inner peripheral portion of each of the wheel drives 34 at the vehicle rear side of the worm wheel 34A. The predetermined number of meshing claws 34B are disposed at even spacings around the circumferential direction of the wheel drive 34. The meshing claws 34B extend toward the vehicle rear side and are elastic. The leading ends (vehicle rear side ends of the meshing claws 34B project toward the radial direction inside of the respective wheel drives 34.

A rod drive 36, which has a substantially circular column shape and serves as a moving member, is coaxially inserted inside each of the wheel drives 34. Each of the rod drives 36 projects through the covering wall 16C toward the vehicle rear side. One of the rod drives 36 is disposed above (or alternatively below) a center axis line of the support wall 16B of the visor body 16. The other of the rod drives 36 is disposed at the vehicle width direction outside (or alternatively at the vehicle width direction inside) of the center axis line of the support wall 16B.

Portions other than leading end portions (vehicle rear side end portions) of the rod. drives 36 configure respective threads 36A. The leading ends of the meshing claws 34B of the wheel drives 34 are meshed (engaged) with the respective threads 36A. The leading end portions of the rod drives 36 have substantially spherical shapes.

A mirror body 38, which serves as a visual recognition means, is housed inside the housing wall 16A of the visor body 16. The entire periphery and vehicle front side of the mirror body 38 is covered by the housing wall 16A.

A mirror 40, which has a substantially rectangular plate shape and serves as a visual recognition portion is provided at a vehicle rear side portion of the mirror body 38. The front face of the mirror 40 is exposed at the vehicle rear side of the visor body 16. A mirror face 40A (a surface of a reflecting layer on the back side) of the mirror 40 faces toward the vehicle rear side. Vehicle rearward visual recognition by an occupant (in particular the driver) of the vehicle is assisted by the mirror 40.

A mirror holder 42, which is made from resin and has a substantially rectangular plate shape, is provided as a sliding body on a vehicle front side portion of the mirror body 38. The entire periphery of the mirror holder 42 fixes (retains) the entire periphery of the mirror 40 and the mirror holder 42 covers the vehicle front side (back side) of the mirror 40.

An attachment wall 42A, which has a substantially tube shape and serves as an attachment portion, is formed to the mirror holder 42 at a vehicle front side of a central position (center of gravity position) of the mirror 40. The attachment wall 42A is disposed coaxially to the support wall 16B of the visor body 16. The attachment wall 42A has a substantially spherical wall profile, with an inner diameter dimension of the attachment wall 42A gradually increasing on progression toward the vehicle rear. The retention ball 22A of the retention tube 22 of the visor body 16 is fit-inserted inside the attachment wall 42A. The attachment wall 42A is thereby retained on the retention ball 22A so as to be capable of tilting and sliding.

A sliding wall 42B, which has a substantially cylindrical shape and serves as a sliding portion, is integrally provided at a vehicle front side of the mirror holder 42. The sliding wall 42B is disposed coaxially to the support wall 16B of the visor body 16. The sliding wall 42B has a spherical wall profile, and the external diameter dimension of the sliding wall 42B gradually increases on progression toward the vehicle rear. The outer peripheral face of the sliding wall 42B contacts the inner peripheral face of the support wall 16B, and the sliding wall 42B is supported by the inner peripheral face of the support wall 16B so as to be capable of tilting and sliding.

The mirror holder 42 includes a pair of swivel walls 42C, which each have a substantially tube shape and serve as a swivel portion, formed at a radial direction inside of the sliding wall 42B. One of the swivel walls 42C is disposed above (or alternatively below) the center axis line of the support wall 16B of the visor body 16. The other of the swivel walls 42C is disposed at the vehicle width direction outside (or alternatively at the vehicle width direction inside) of the center axis line of the support wall 16B. The swivel walls 42C are disposed with the center axis lines thereof parallel to the center axis line of the support wall 16B of the visor body 16. The swivel walls 42C each have a substantially spherical wall profile, and the inner diameter dimension of the swivel walls 42C gradually increases on progression from the two vehicle front-rear direction end sides of the swivel walls 42C toward the vehicle front-rear direction center thereof.

The leading end portions of the rod drives 36 of the mirror face adjustment mechanism 28 are fit-inserted into and retained by the swivel walls 42C. The swivel walls 42C permit swiveling with respect to the leading end portion of the respective rod drives 36, and restrict axial rotation of the rod drives 36. Thus, as stated above, in the mirror face adjustment mechanism 28, as the wheel drives 34 (including the meshing claws 34B) are rotated, the meshing position of the leading ends of the meshing claws 34B with the threads 36A of the respective rod drives 36 is displaced, and the respective rod drives 36 are moved (slide) in the vehicle front-rear direction (axial direction).

Next, explanation follows regarding operation of the present exemplary embodiment.

In the vehicle door mirror device 10 configured as described above, the swing body 12B swings with respect to the stand 12A by electrically operating the stowing mechanism 12, and the mirror body 38 (including the visor 14 (the visor body 16 and the visor cover 20), the reinforcement 24, and the mirror face adjustment mechanism 28) swing as a unit with the swing body 12B. The mirror body 38 thereby swings toward the vehicle rear side and the vehicle width direction inside, and the mirror body 38 is stowed. Moreover, the mirror body 38 is flipped out (deployed, returned) by the mirror body 38 being swung toward the vehicle front side and the vehicle width direction outside.

Moreover, when the motors 30 are driven by electrically operating the mirror face adjustment mechanism 28 so as to rotate the worm 32, the wheel drives 34 are rotated, and the rod drives 36 moved in the vehicle front-rear direction. Thus, by the mirror body 38 (the mirror 40 and the mirror holder 42) being tilted by the rod drives 36 in at least one of the up-down direction or the vehicle width direction, the angle of the mirror face 40A of the mirror 40 (i.e. the visual recognition direction of the occupant assisted by the mirror 40) is adjusted in at least one of the up-down direction or the vehicle width direction.

The terminals 44 are provided embedded in the reinforcement 24. The output terminals 44A of the terminals 44 are electrically connected to the main body 30A of the motors 30.

When manufacturing the reinforcement 24, first the reinforcement 24 is molded (insert molded) using a mold (not illustrated in the drawings) with the terminals 44 in a state inserted into the reinforcement 24. When molding the reinforcement 24, portions at the leading end side of two of the terminals 44 are coupled together by a coupling portion (not illustrated in the drawings). Moreover, a pair of first support columns (not illustrated in the drawings), which have rectangular column shapes and serve as support members, and four pairs of second support columns (not illustrated in the drawings), which have circular column shapes and serve as support members, are provided inside the mold. When the reinforcement 24 is being molding, the coupling portion of two of the terminals 44 (including each of the terminals 44 in the vicinity of the coupling portion) is supported between the pair of first support columns, and portions of the terminals 44 in the vicinity of the output terminals 44A are supported between each of the respective pairs of second support columns. This thereby restricts movement of the terminals 44 with respect to the mold.

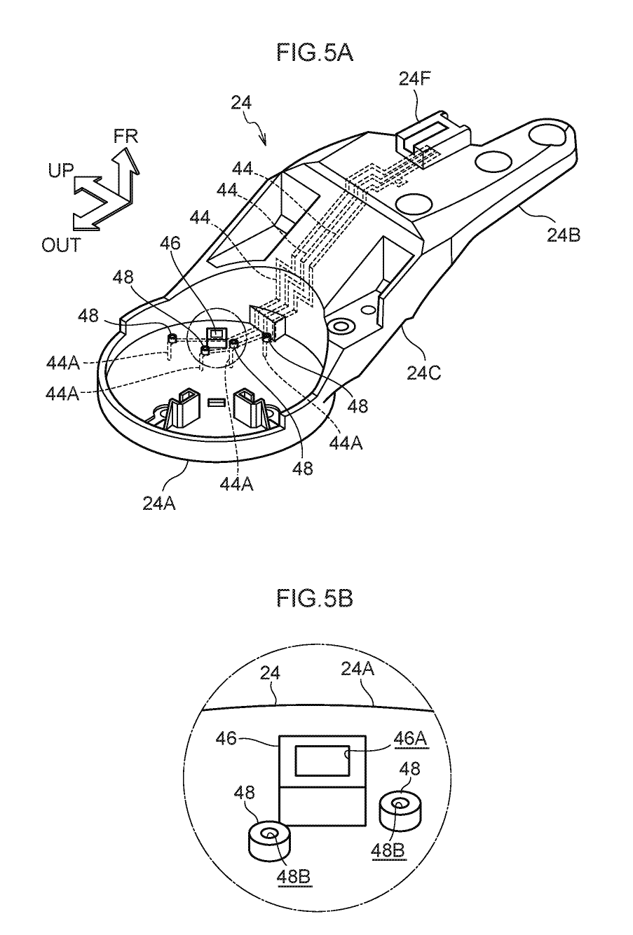

Therefore, as illustrated in FIG. 5A and FIG. 5B, when the reinforcement 24 has been molded, first exposing holes 46B, which each have a rectangular shape and serve as an exposing hole, are formed in the reinforcement 24 by the first support columns, and second exposing holes 48B, which each have a circular shape and serve as an exposing hole, are formed in the reinforcement 24 by the second support columns. The coupling portion of the two terminals 44 (including each of the terminals 44 in the vicinity of the coupling portion) is exposed to outside the reinforcement 24 by the first exposing holes 46B. The portions of the terminals 44 in the vicinity of the output terminals 44A are exposed to outside the reinforcement 24 by the second exposing holes 48B. Thereby, after the reinforcement 24 has been molded, the coupling portion of the two terminals 44 is severed (for example, at least part of die coupling portion is removed) through the first exposing holes 46B, and the two terminals 44 are parted. Moreover, conductivity testing of the terminals 44 may be performed through the second exposing holes 48B.

When molding the reinforcement 24, the mold is used to form the first protrusion portions 46 and the second protrusion portions 48 on the vehicle front side face and the vehicle rear side face of the reinforcement 24. The first protrusion portions 46, which have rectangular tube shapes and serve as protrusion portions, are formed around the entire periphery of the first exposing holes 46B. The second protrusion portions 48, which have circular tube shapes and serve as protrusion portions, are formed around the entire periphery of the second exposing holes 48B. Moreover, after the reinforcement 24 has been molded, the first protrusion portions 46 are pressed and moved into the first exposing holes 46B while in a melted state by heat-crimping, and caused to oppose the parted portion (including each of the terminals 44 in the vicinity of the parted portion) of the two terminals 44, and the second protrusion portions 48 are pressed and moved into the second exposing holes 48B while in a melted state by heat-crimping, and caused to oppose the portions of the terminals 44 in the vicinity of the output terminals 44A.

Thereby, as illustrated in FIG. 4A and FIG. 4B, the first protrusion portions 46 close off the first exposing holes 46B and are solidified so as to inhibit water (liquid) from infiltrating to the parted portions of the two terminals 44 (including each of the terminals 44 in the vicinity of the parted portion), and the second protrusion portions 48 close off the second exposing holes 48B and are solidified so as to inhibit water (liquid) from infiltrating to the portions of the terminals 44 in the vicinity of the output terminals 44A. Due to being able to inhibit infiltration of water to the terminals 44 embedded in the reinforcement 24 in this manner, corrosion can be suppressed from being generated on the terminals 44 embedded in the reinforcement 24, enabling the insulated state of the terminals 44 embedded in the reinforcement 24 to be secured. Moreover, infiltration of water to the terminals 44 embedded in the reinforcement 24 can be inhibited without needing an additional component, obviating the need to increase the number of components, and enabling costs to be reduced.

Moreover, the first protrusion portions 46 close off the first exposing holes 46B while in a state projecting from the reinforcement 24, and the second protrusion portions 48 close off the second exposing holes 48B while in a state projecting from the reinforcement 24. This enables the first protrusion portions 46 to effectively close off the first exposing holes 46B, enables the second protrusion portions 48 to effectively close off the second exposing holes 48B, and enables water to be effectively inhibited from infiltrating to the terminals 44 embedded in the reinforcement 24.

Moreover, the first protrusion portions 46 and the second protrusion portions 48 are respectively provided on the vehicle front side face and the vehicle rear side face of the reinforcement 24. The parted portions of the two terminals 44 (including each of the terminals 44 in the vicinity of the parted portion) are disposed between the pair of first protrusion portions 46. The portions of the terminals 44 in the vicinity of the output terminals 44A are disposed between the pairs of second protrusion portions 48. This enables water infiltration to the terminals 44 embedded in the reinforcement 24 to be inhibited from both the vehicle front side face and the vehicle rear side face of the reinforcement 24.

Moreover, the first protrusion portions 46 oppose the parted portions of the two terminals 44. Thus after the two terminals 44 have been parted through the first exposing holes 46B in a state in which the coupling portion of the two terminals 44 was exposed to outside the reinforcement 24 by the first exposing holes 46B in the reinforcement 24, the first protrusion portions 46 can be provided so as to oppose the parted portions of the two terminals 44. Thereby, even in cases in which the two terminals 44 are coupled together while molding the reinforcement 24, the two terminals 44 can still be parted prior to pressing and moving the first protrusion portions 46 into the first exposing holes 46B while in a melted state by heat-crimping.

Moreover, when mold the reinforcement 24, the first protrusion portions 46 are formed around the entire periphery of the first exposing holes 46B in the reinforcement 24, and the second protrusion portions 48 are formed around the entire periphery of the second exposing holes 48B in the reinforcement 24. Thus the first recess portions 46A are formed at the leading end portions of the first protrusion portions 46 by pressing and moving the first protrusion portions 46 from the entire periphery of the first exposing holes 46B into the first exposing holes 46B while the first protrusion portions 46 are in a melted state by heat-crimping. The second recess portions 48A are formed at the leading end portions of the second protrusion portions 48 by pressing and moving the second protrusion portions 48 from the entire periphery of the second exposing holes 48B into the second exposing holes 48B while the second protrusion portions 48 are in a melted state by heat-crimping. This enables the first protrusion portions 46 to easily close off the first exposing holes 46B from around the entire periphery, and enables the second protrusion portions 48 to easily close off the second exposing holes 48B from around the entire periphery, enabling excellent inhibition by the first protrusion portions 46 and the second protrusion portions 48 of water from infiltrating to the terminals 44 embedded in the reinforcement 24.

Note that in the present exemplary embodiment the first protrusion portions 46 and the second protrusion portions 48 (protrusion portions) are respectively formed at perimeters of the first exposing holes 46B and the second exposing holes 48B (exposing holes) when the reinforcement 24 is being molded. However, the protrusion portions are not necessarily formed at the exposing hole perimeters when the reinforcement 24 is being molded.

Moreover, in the present exemplary embodiment the first protrusion portions 46 and the second protrusion portions 48 are integrally molded to the reinforcement 24. However, at least one of the first protrusion portions 46 or the second protrusion portions 48 may be provided as a separate body to the reinforcement 24 and formed on the reinforcement 24 by heat-crimping after the reinforcement 24 itself has been molded. In such cases the at least one of the first protrusion portions 46 or the second protrusion portions 48 may made from a material different to that of the reinforcement 24.

Moreover, in the present exemplary embodiment, the first protrusion portions 46 and the second protrusion portions 48 (solidified portions) that respectively close off the first exposing holes 46B and the second exposing holes 48B (exposing holes) are projected from the reinforcement 24. However, the solidified portions that close off the exposing holes are not necessarily projected from the reinforcement 24, and the surface of the solidified portions may be in the same plane as, or have an indented shape with respect to, the surface of the reinforcement 24.

Moreover, in the present exemplary embodiment, the terminals 44 of the reinforcement 24 are electrically connected to the mirror face adjustment mechanism 28. However, the terminals 44 of the reinforcement 24 may be electrically connected to the stowing mechanism 12. Moreover, a lamp (indicator lamp or lighting lamp) may be provided to the vehicle door mirror device 10, and the terminals 44 of the reinforcement 24 electrically connected to the lamp.

Moreover, in the present exemplary embodiment, the mirror body 38 serves as a visual recognition means. However, a camera to assist visual recognition of an occupant by imaging may serve as the visual recognition means. In such cases the terminals 44 of the reinforcement 24 may be electrically connected to the camera.

Furthermore, in the present exemplary embodiment, the vehicle door mirror device 10 (operating mechanism) is installed at the outside of a door of a vehicle. However, the operating mechanism may be installed at another position on a vehicle, or to something other than a vehicle.

The entire content of the disclosure of Japanese Patent Application No. 2016-20044 filed on Feb. 4, 2016 is incorporated by reference in the present specification.

### EXPLANATION OF THE REFERENCE NUMERALS

10 vehicle door mirror device (operating mechanism)
24 reinforcement (layout member)
38 mirror body (visual recognition means)
44 terminal (wiring)
46 first protrusion portion (solidified portion, protrusion portion)
46A first recess portion (recess portion)
46B first exposing hole (exposing hole)
48 second protrusion portion (solidified portion, protrusion portion)
48A second recess portion (recess portion)
48B second exposing hole (exposing hole)

1. An operating device comprising:
an operating mechanism that is electrically operated;
a layout member including wiring electrically connected to the operating mechanism and disposed within the layout member; and
a solidified portion that is provided at the layout member, that is solidified separately from a perimeter thereof, that opposes the wiring, and that inhibits infiltration of liquid to the wiring.

2. The operating device of claim 1, wherein the solidified portion is provided on one side face and another side face of the layout member, and the wiring is disposed between the solidified portion and the solidified portion.

3. The operating device of claim 1, wherein the wiring is parted at a solidified portion opposing portion.

4. The operating device of claim 1, wherein the solidified portion is projected from the layout member.

5. The operating device of claim 4, wherein a recess portion is provided in a projecting leading end portion of the solidified portion.

6. A method of manufacturing an operating device that includes an electrically operated operating mechanism and a layout member including wiring electrically connected to the operating mechanism and disposed within the layout member, the operating device manufacturing method comprising:
providing an exposing hole in the layout member to expose the wiring; and
moving a portion of a perimeter of the exposing hole of the layout member into the exposing hole while in a melted state to cause the portion to oppose the wiring, and solidifying the portion so as to configure a solidified portion and to inhibit infiltration of liquid to the wiring.

7. The operating device manufacturing method of claim 6, wherein:
a protrusion portion is provided at the exposing hole perimeter of the layout member; and
the solidified portion is configured by the protrusion portion by moving the protrusion portion into the exposing hole while in a melted state so as to cause the protrusion portion to oppose the wiring, so as to inhibit infiltration of liquid to the wiring.

8. The operating device manufacturing method of claim 7, wherein the protrusion portion is provided at an entire periphery of the exposing hole of the layout member.

9. The operating device manufacturing method of claim 6, wherein the solidified portion is projected from the layout member.
